(19) United States
(12) Patent Application Publication
(10) Pub. No.: US 2016/0079365 A1
(43) Pub. Date: Mar. 17, 2016

(54) NONVOLATILE SEMICONDUCTOR MEMORY DEVICE AND METHOD FOR MANUFACTURING SAME

(71) Applicant: Kabushiki Kaisha Toshiba, Minato-ku (JP)

(72) Inventor: Kotaro NODA, Yokkaichi (JP)

(73) Assignee: Kabushiki Kaisha Toshiba, Minato-ku (JP)

(21) Appl. No.: 14/637,654

(22) Filed: Mar. 4, 2015

(30) Foreign Application Priority Data
Sep. 12, 2014 (JP) 2014-186188

(51) Int. Cl. H01L 29/10; H01L 27/115; H01L 21/764; H01L 29/423

(52) U.S. Cl. CPC H01L 29/1033; H01L 29/42364; H01L 27/11582; H01L 21/764

(57) ABSTRACT

According one embodiment, a memory device includes: a stacked body provided on a foundation layer, the stacked body including electrode layers stacked alternately with first insulating layers, at least one of the plurality of electrode layers including a first portion and a second portion, a first length between the first portion and the foundation layer being longer than a second length between the second portion and the foundation layer, difference between the first length and the second length increasing toward the foundation layer; a semiconductor member piercing the second portion, the semiconductor member extending in a direction of the stacking of the electrode layers and the first insulating layers, the semiconductor member including a region where maximum length of the semiconductor member cut perpendicularly to the direction decreases toward the foundation layer; and a memory film provided between the semiconductor member and each of the electrode layers.

### CROSS-REFERENCE TO RELATED APPLICATIONS

This application is based upon and claims the benefit of priority from Japanese Patent Application No. 2014-186188, filed on Sep. 12, 2014; the entire contents of which are incorporated herein by reference.

### FIELD

Embodiments described herein relate generally to a nonvolatile semiconductor memory device and a method for manufacturing the same.

### BACKGROUND

There is a nonvolatile semiconductor memory device that is manufactured by forming a stacked body including alternately-stacked control gate layers and insulating layers, making a memory hole by etching, forming a memory film on an inner wall of the memory hole, and subsequently forming a channel body layer on the inner wall.

However, the aspect ratio of the memory hole increases as the number of stacks of the stacked body increases; and, for example, it is difficult to make the lower portion of the memory hole in a straight configuration. As a result, when programming or erasing data to or from the memory film, the electric field strength that is applied to the memory film is different between the upper portion and lower portion of the memory hole; and the reliability of the nonvolatile semiconductor memory device may decrease.

### BRIEF DESCRIPTION OF THE DRAWINGS

FIG. 1A is a schematic cross-sectional view showing a nonvolatile semiconductor memory device according to an embodiment and FIG. 1B is a schematic plan view showing the nonvolatile semiconductor memory device according to the embodiment;

FIG. 2A to FIG. 8 are schematic cross-sectional views showing manufacturing processes of the nonvolatile semiconductor memory device according to the embodiment;

FIG. 9A and FIG. 9B are schematic views showing a nonvolatile semiconductor memory device according to a reference example;

FIG. 10 shows a relationship between a height difference of an electrode layer and a cross-sectional area of a channel body layer for the nonvolatile semiconductor memory device according to the embodiment; and

FIG. 11A and FIG. 11B are schematic cross-sectional views showing electrode layers of the nonvolatile semiconductor memory device according to the embodiment.

### DETAILED DESCRIPTION

In general, according one embodiment, a foundation layer; a stacked body provided on the foundation layer, the stacked body including a plurality of first electrode layers stacked alternately with a plurality of first insulating layers, at least one of the plurality of first electrode layers including a first portion and a second portion, a first length between the first portion and the foundation layer being longer than a second length between the second portion and the foundation layer, difference between the first length and the second length increasing toward the foundation layer; a semiconductor member piercing the second portion in the stacked body, the semiconductor member extending in a direction of the stacking of the plurality of first electrode layers and the plurality of first insulating layers, the semiconductor member including a region where maximum length of the semiconductor member cut perpendicularly to the direction decreases toward the foundation layer; and a memory film provided between the semiconductor member and each of the plurality of first electrode layers.

An embodiment will now be described with reference to the drawings. In the description hereinbelow, the same members are marked with the same reference numerals; and a description is omitted as appropriate for members once described.

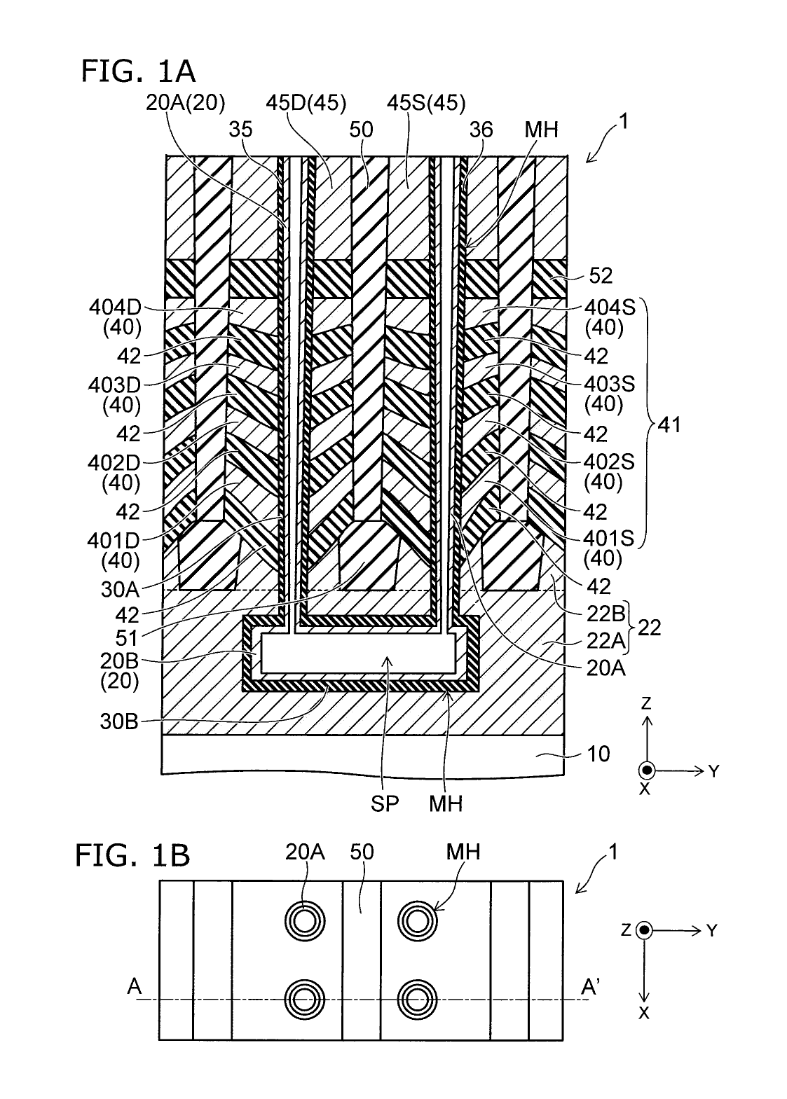

FIG. 1A is a schematic cross-sectional view showing a nonvolatile semiconductor memory device according to the embodiment; and FIG. 1B is a schematic plan view showing the nonvolatile semiconductor memory device according to the embodiment.

A cross section at a position along line A-A′ in FIG. 1B is shown in FIG. 1A.

For convenience of description, an XYZ orthogonal coordinate system is introduced in FIGS. 1A and 1B. In the coordinate system, two mutually-orthogonal directions parallel to a major surface of a foundation layer 10 are taken as an X-direction and a Y-direction; and a direction orthogonal to both the X-direction and the Y-direction is taken as a Z-direction.

The nonvolatile semiconductor memory device 1 is a NAND nonvolatile memory that can freely and electrically erase and program data and retain the memory content even when the power supply is OFF. The nonvolatile semiconductor memory device 1 shown in FIGS. 1A and 1B is normally called BiCS (Bit Cost Scalable) flash memory.

In the nonvolatile semiconductor memory device 1, a back gate 22 is provided on the foundation layer 10. The back gate 22 includes, for example, a back gate 22A, and a back gate 22B having an upper surface that has an unevenness. The back gate 22 is, for example, a semiconductor layer. The back gate 22 is, for example, a silicon (Si)-containing layer to which an impurity element is added.

The foundation layer 10 includes, for example, an insulator. A semiconductor substrate (not shown) is provided under the foundation layer 10. Active elements such as transistors, etc., and passive elements such as resistors, capacitors, etc., may be provided in the semiconductor substrate. Interconnects that are linked to these elements may be drawn out in the foundation layer 10.

Electrode layers 401D, 402D, 403D, and 404D on the drain side and electrode layers 401S, 402S, 403S, and 404S on the source side are stacked on the back gate 22 as an example in FIG. 1A.

An insulating layer 42 is provided between the electrode layers above and below. The insulating layer 42 includes, for example, silicon oxide, silicon nitride, etc. At least one of the electrode layers 401D to 404D or 401S to 404S includes a portion of increasing height from the foundation layer 10 and a portion of decreasing height from the foundation layer 10.

An insulating layer 50 is provided between the electrode layer 401D and the electrode layer 401S, between the electrode layer 402D and the electrode layer 402S, between the electrode layer 403D and the electrode layer 403S, and between the electrode layer 404D and the electrode layer 404S. The insulating layer 50 includes, for example, silicon oxide, silicon nitride, etc.

The number of layers of electrode layers 401D to 404D and the number of layers of electrode layers 401S to 404S are arbitrary and are not limited to the numbers shown in FIG. 1A. The electrode layers 401D to 404D and 401S to 404S may be generally referred to as the electrode layers 40. The electrode layers 40 are, for example, silicon-containing layers to which an impurity element such as boron (B) or the like is added. The electrode layers 40 are conductive. The structural body in which the electrode layers 40 and the insulating layers 42 are stacked alternately is referred to as a stacked body 41.

An insulating layer 51 is provided between the stacked body 41 and the foundation layer 10. The insulating layer 51 includes, for example, silicon oxide, silicon nitride, tantalum oxide, etc. The insulating layer 51 is provided between the back gate 22 and the electrode layer (the electrode layer 401D or the electrode layer 401S) positioned at the lowermost layer of the multiple electrode layers 40. The insulating layer 51 is provided between the back gate 22 and the portion of increasing height of the electrode layer 401D from the foundation layer 10, i.e., the portion where the electrode layer 401D swells upward. Or, the insulating layer 51 is provided between the back gate 22 and the portion of increasing height of the electrode layer 401S from the foundation layer 10, i.e., the portion where the electrode layer 401S swells upward.

A selection gate electrode 45D on the drain side is provided on the electrode layer 404D with an insulating layer 52 interposed. The insulating layer 52 includes, for example, silicon oxide, silicon nitride, etc. The selection gate electrode 45D is, for example, a conductive silicon-containing layer to which an impurity is added. A selection transistor on the drain side is formed of the selection gate electrode 45D, a channel body layer (semiconductor member) 20A, and a gate insulator film 35.

A selection gate electrode 45S is provided on the electrode layer 404S with the insulating layer 52 interposed. The selection gate electrode 45S is, for example, a conductive silicon-containing layer to which an impurity is added. A selection transistor on the source side is formed of the selection gate electrode 45S, the channel body layer 20A, and a gate insulator film 36.

The selection gate electrode 45D and the selection gate electrode 45S are separated in the Y-direction by the insulating layer 50. The selection gate electrode 45D and the selection gate electrode 45S may be generally referred to as a selection gate electrode 45. The selection gate electrode 45D is connected to a bit line (not shown) of the nonvolatile semiconductor memory device; and the selection gate electrode 45S is connected to a source line (not shown) of the nonvolatile semiconductor memory device.

A pair of memory holes MH that extend in the Z-direction is made in the stacked body 41. For example, the memory holes MH are the holes prior to forming the channel body layer 20A and a memory film 30A (described below). The memory holes MH communicate with a hollow portion SP made in the back gate 22 to make a hole having a U-shaped configuration. The memory holes MH that are made in the stacked body 41 have tapered configurations in which the inner diameters are narrower toward the foundation layer 10.

The channel body layer 20A is provided inside the memory holes MH. The channel body layer 20A is, for example, a silicon-containing layer. The memory film 30A is provided between the channel body layer 20A and the inner walls of the memory holes MH. In other words, the memory film 30A is provided between the channel body layer 20A and each of the multiple electrode layers 40.

For example, the memory film 30A has an ONO (Oxide-Nitride-Oxide) structure in which a silicon nitride film is interposed between silicon oxide films. For example, a charge storage film is provided between a silicon oxide film contacting the electrode layers 40 and a silicon oxide film contacting the channel body layer 20A. The charge storage film includes, for example, silicon nitride.

The gate insulator film 35 is provided between the channel body layer 20A and the selection gate electrode 45D.

The gate insulator film 36 is provided between the channel body layer 20A and the selection gate electrode 45S.

A channel body layer 20B is provided inside the hollow portion SP. The channel body layer 20B is connected to a pair of channel body layers 20A. The channel body layer 20B is, for example, a silicon-containing layer. An insulating film 30B is provided between the channel body layer 20B and the inner wall of the hollow portion SP. The channel body layer 20A and the channel body layer 20B are generally referred to as a channel body layer 20. A back gate transistor is formed of the back gate 22, the channel body layer 20B, and the insulating film 30B.

Although a channel body layer 20 having a pipe-like configuration is shown in FIGS. 1A and 1B as an example, a channel body layer 20 that is not hollow also is included in the embodiment.

Manufacturing processes of the nonvolatile semiconductor memory device 1 will now be described. Unless otherwise specified, film formation is performed by a method such as CVD (Chemical Vapor Deposition), sputtering, printing, plating, etc. The patterning of covering films and layers is performed by photolithography and etching.

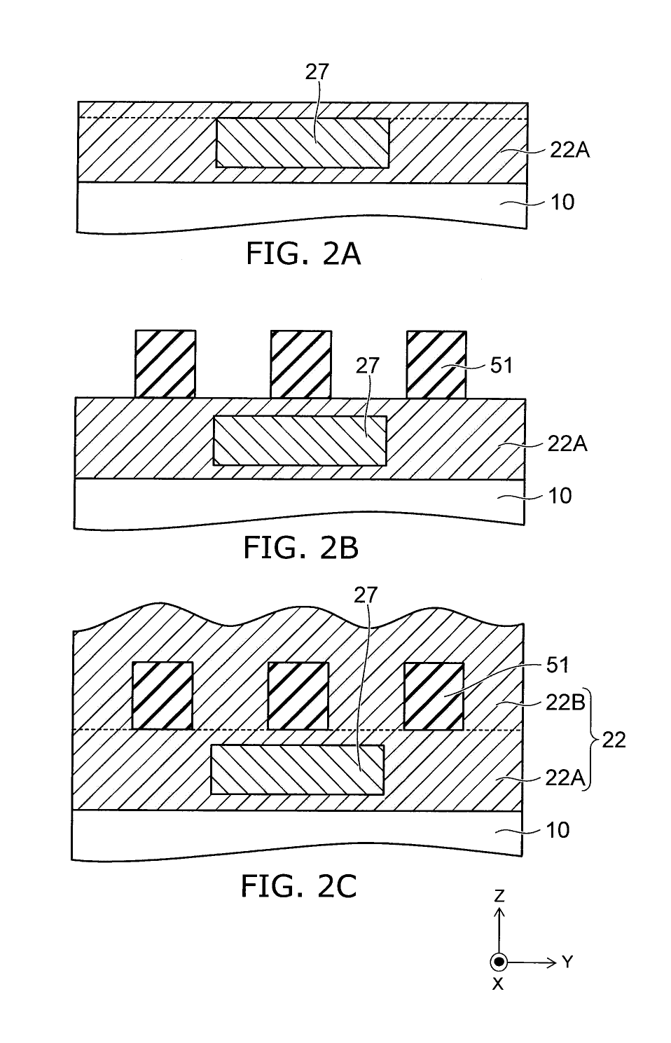

FIG. 2A to FIG. 8 are schematic cross-sectional views showing manufacturing processes of the nonvolatile semiconductor memory device according to the embodiment.

As shown in FIG. 2A, the back gate 22A is formed on the foundation layer 10. A sacrificial layer 27 is pre-formed selectively inside the back gate 22A. The sacrificial layer 27 includes non-doped amorphous silicon.

Then, as shown in FIG. 2B, the insulating layer 51 is formed on the back gate 22A.

Continuing as shown in FIG. 2C, the back gate 22B is formed on the back gate 22A and on the insulating layer 51. At this stage, a structural body is formed in which the insulating layer 51 is formed inside the back gate 22.

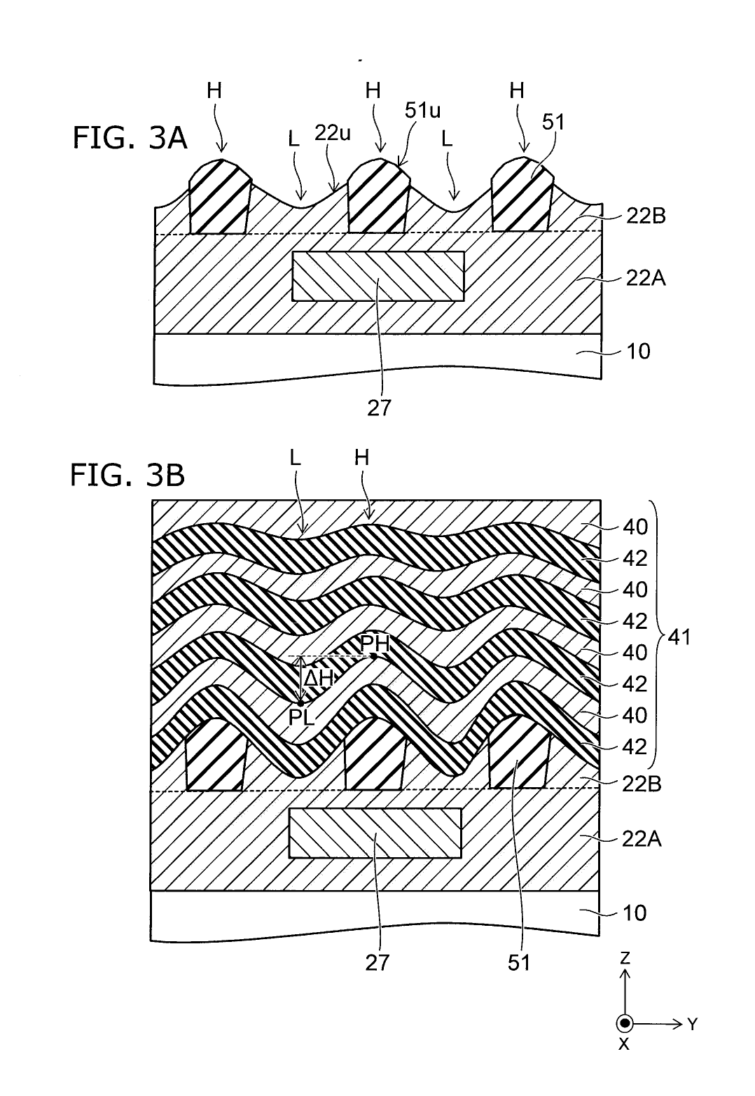

Then, as shown in FIG. 3A, etch-back of an upper surface 22u of the back gate 22 is performed until the insulating layer 51 protrudes from the upper surface 22u of the back gate 22. That is, etch-back of the upper surface 22u of the back gate 22 is performed by selecting an etching gas so that the etching rate of the back gate 22B is faster than the etching rate of the insulating layer 51. In the etch-back, over-etching is performed so that the upper surface 22u of the back gate 22 after the etch-back is lower than the insulating layer 51. The corners of the insulating layer 51 are slightly rounded by the etching.

Thereby, after the etch-back, the upper surface made of an upper surface 51u of the insulating layer 51 combined with the upper surface 22u of the back gate 22 is a surface having a substantially wave-like configuration. That is, the combined upper surface of the upper surface 51u of the insulating layer 51 and the upper surface 22u of the back gate 22 includes a portion H having a high height from the foundation layer 10 and a portion L having a low height from the foundation layer 10.

Then, as shown in FIG. 3B, the stacked body 41 is formed on the insulating layer 51 and on the back gate 22.

Here, the stacked body 41 is affected by the uneven configuration formed of the high portion H and the low portion L described above. That is, the electrode layers 40 that are deposited on the uneven structure include the portions H of relatively increasing height from the foundation layer 10 and the portions L of relatively decreasing height from the foundation layer 10. Similarly, the insulating layers 42 include the portions H of relatively increasing height from the foundation layer 10 and the portions L of relatively decreasing height from the foundation layer 10.

The effect of the uneven configuration is relaxed toward the upper layers of the stacked body 41. That is, a height difference ΔH between the high portion H and the low portion L decreases toward the upper layers of the multiple electrode layers 40. In other words, for the multiple electrode layers 40, the height difference ΔH between the high portion H and the low portion L increases toward the foundation layer 10. Here, the height difference ΔH is defined as the difference between the height of the upper surface of the high portion H and the height of the upper surface of the low portion L for each of the electrode layers 40 (the height difference ΔH: the difference between the height of a point PH and the height of a point PL).

In other words, a first distance between the portion H and the foundation layer 10 is longer than a second distance between the portion L and the foundation layer 10. The difference between the first distance and the second distance increases toward the foundation layer 10.

For example, processing such as CMP (Chemical Mechanical Polishing), etc., of the electrode layer 40 of the uppermost layer may be performed. In the case where the processing such as CMP, etc., is performed, the upper surface of the electrode layer 40 of the uppermost layer becomes flat as shown.

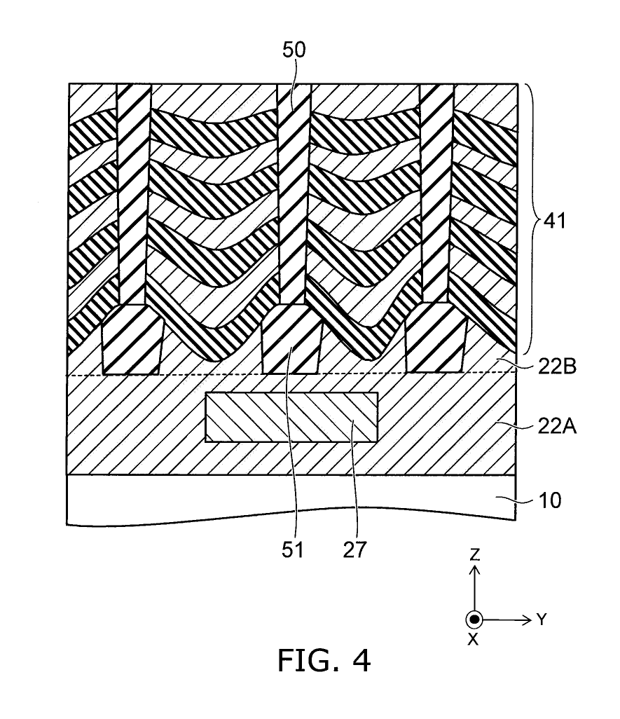

Then, as shown in FIG. 4, the insulating layer 50 that contacts the insulating layer 51 is formed. The insulating layer 50 extends in the Z-direction through the stacked body 41. To form the insulating layer 50, a trench into which the insulating layer 50 is filled is pre-made by RIE (Reactive Ion Etching); and the insulating layer 51 functions as an etching stopper layer of the RIE.

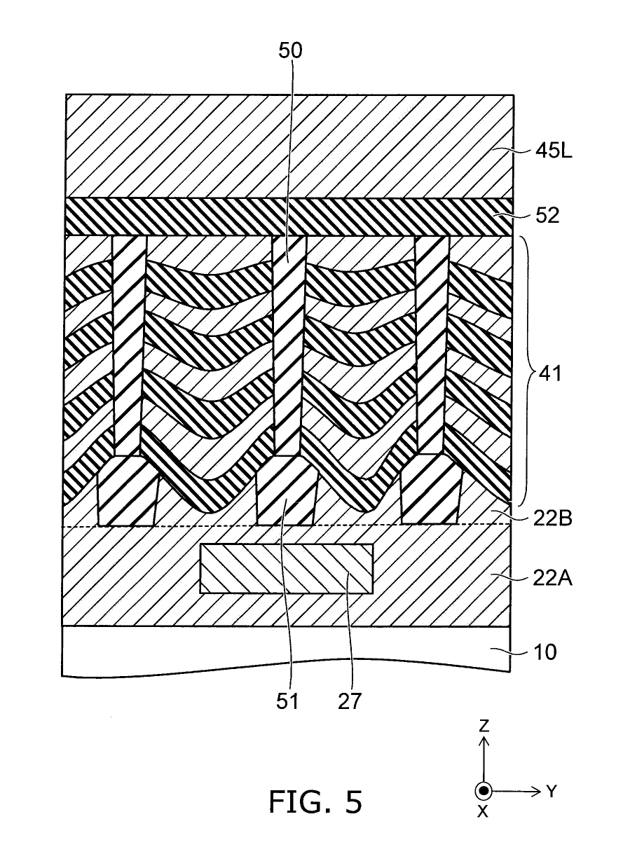

Continuing as shown in FIG. 5, the insulating layer 52 is formed on the stacked body 41 and on the insulating layer 50. Continuing, a selection gate electrode layer 45L is formed on the insulating layer 52.

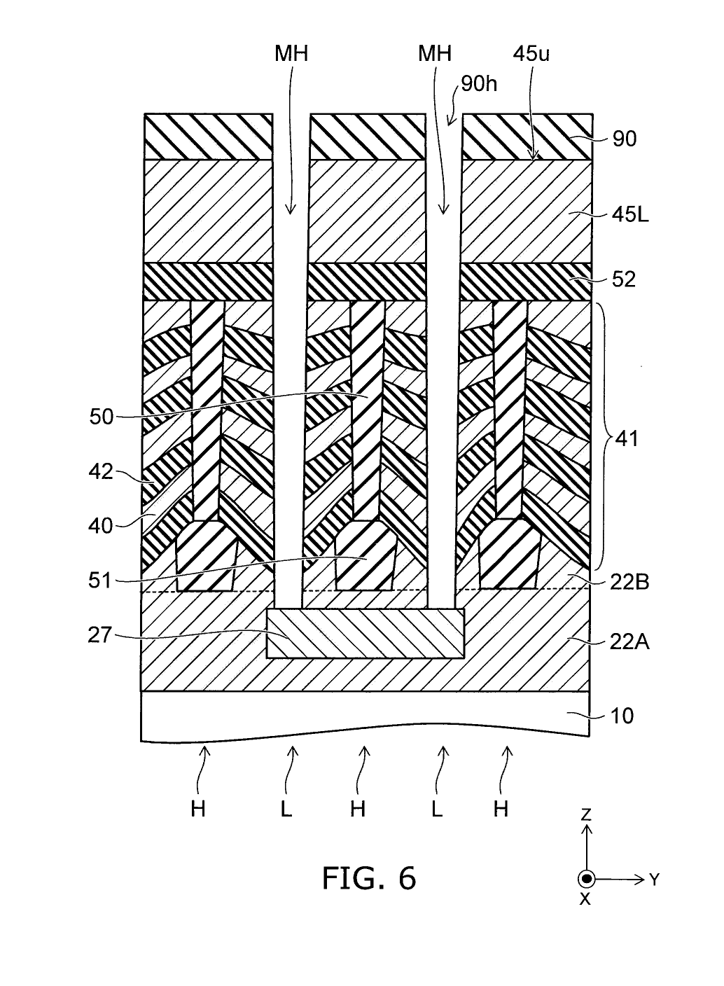

Then, as shown in FIG. 6, a mask layer 90 is patterned on the selection gate electrode layer 45L. An opening 90h is selectively provided in the mask layer 90. Continuing, the selection gate electrode layer 45L that corresponds to the bottom of the opening 90h and the insulating layer 52, the stacked body 41, and the back gate 22 under the opening 90h are removed by RIE.

Thereby, the memory hole MH is made to pierce from an upper surface 45u of the selection gate electrode layer 45L to the sacrificial layer 27. The memory hole MH extends through the stacked body 41 in the direction (the Z-direction) in which the multiple electrode layers 40 and the multiple insulating layers 42 are stacked alternately. The memory hole MH that is made in the stacked body 41 pierces the portions L of decreasing height of the electrode layers 40.

Here, the lower side of the memory hole MH made in the stacked body 41 easily has a tapered configuration as the aspect ratio of the memory hole MH increases. For example, when the memory hole MH is cut perpendicularly to the Z-direction, the memory hole MH includes a region where the area of the memory hole MH enclosed with the outline of the memory hole MH decreases toward the foundation layer 10.

Here, length at most length is defined as maximum length in length of the memory hole MH in X direction and Y direction when the memory hole MH is cut perpendicularly to the Z-direction. The memory hole MH includes a region where the maximum length decreases toward the foundation layer 10.

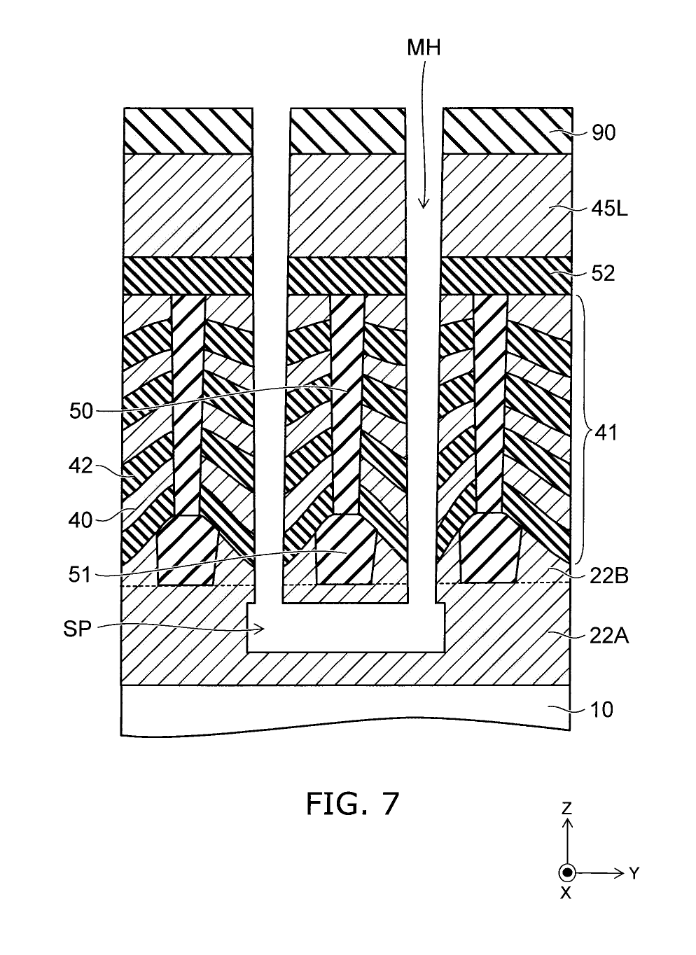

Then, as shown in FIG. 7, the sacrificial layer 27 is removed through the memory holes MH. For example, the removal of the sacrificial layer 27 is performed by wet etching using an alkaline solution such as a KOH solution, etc. Thereby, a space is made in which the memory holes MH communicate with the hollow portion SP.

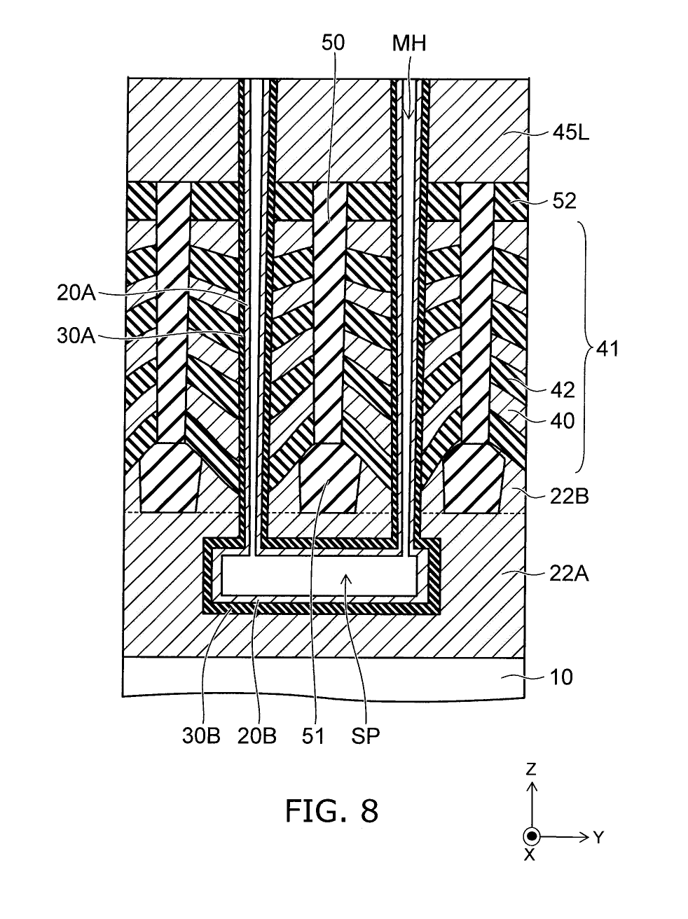

Continuing as shown in FIG. 8, the memory film 30A and the channel body layer 20A are formed in this order on the inner walls of the memory holes MH. The insulating film 30B and the channel body layer 20B are formed in this order on the inner wall of the hollow portion SP. The memory film 30A and the insulating film 30B are formed simultaneously; and the channel body layer 20A and the channel body layer 20B are formed simultaneously.

At this stage, the channel body layer 20 is formed of a pair of channel body layers 20A linked to the channel body layer 20B. The channel body layers 20A extend in the Z-direction through the stacked body 41 while piercing the low portion L of each of the electrode layers 40.

Subsequently, as shown in FIG. 1A, the insulating layer 50 is extended to divide the selection gate electrode layer 45L into the selection gate electrode 45D on the drain side and the selection gate electrode 45S on the source side.

Before describing the effects of the embodiment, effects of a nonvolatile semiconductor memory device according to a reference example will be described.

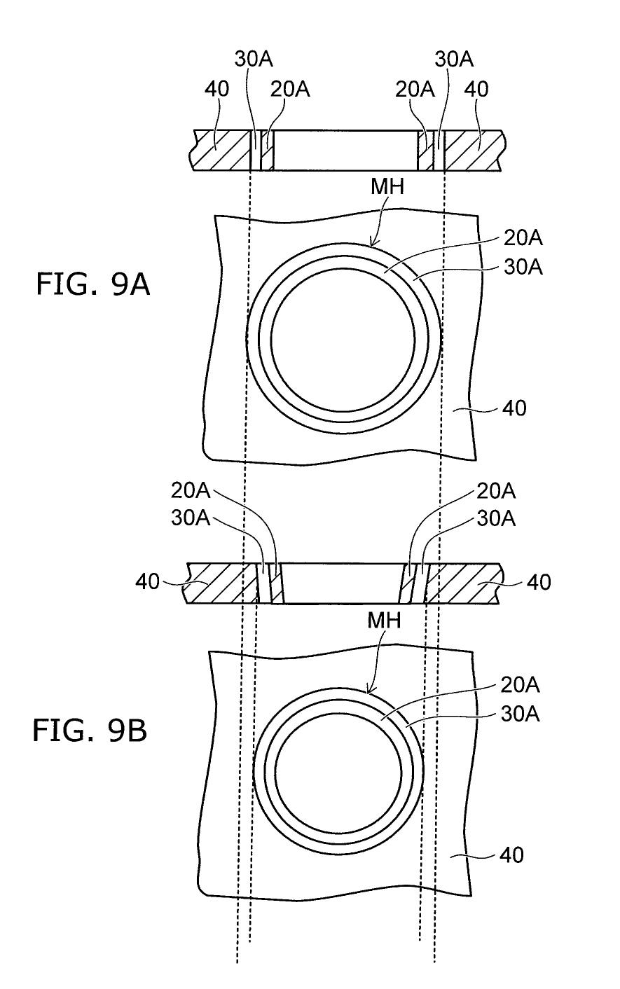

FIG. 9A and FIG. 9B are schematic views showing the nonvolatile semiconductor memory device according to the reference example.

A cross-sectional view and a plan view of the electrode layer 40 at the upper layer of the stacked body 41 is shown in FIG. 9A; and a cross-sectional view and a plan view of the electrode layer 40 at the lower layer of the stacked body 41 is shown in FIG. 9B. In the reference example, each of the electrode layers 40 does not have a wave-like configuration and is parallel to the major surface of the foundation layer 10.

As described above, the lower side of the memory hole MH made in the stacked body 41 easily has a tapered configuration in the case where the aspect ratio is high. Accordingly, the inner diameter of the memory hole MH is narrower at the lower layer shown in FIG. 9B than at the upper layer shown in FIG. 9A.

Thereby, the curvature of the memory film 30A is undesirably higher at the lower layer shown in FIG. 9B than at the upper layer shown in FIG. 9A. Accordingly, in the case where the same potential is applied to each of the electrode layers 40, the electric field that is applied is stronger for the memory film 30A shown in FIG. 9B than for the memory film 30A shown in FIG. 9A. Thereby, the amount of charge that is stored in the memory film 30A is different between the upper layer shown in FIG. 9A and the lower layer shown in FIG. 9B; and the data retention characteristics may decrease.

Conversely, there is an example in which the aspect ratio of the memory hole MH is reduced by reducing the film thickness of the electrode layers 40 and the film thickness of the insulating layers 42. According to such an example, the inner diameter of the memory hole MH is substantially the same for the upper layer shown in FIG. 9A and the lower layer shown in FIG. 9B; and the amount of charge that is stored in the memory film 30A is substantially the same amount for the upper layer shown in FIG. 9A and the lower layer shown in FIG. 9B.

However, providing thin film thicknesses means that the electrode layers 40 above and below are proximal to each other. That is, each of the memory films 30A is easily affected by the electric fields from the electrode layers 40 positioned above and below the memory film 30A. Or, each of the memory films 30A is easily affected by the charge stored in the memory films 30A positioned above and below. Or, in the case where the film thickness of the insulating layer 42 is thin, there are cases where charge is trapped in the insulating layer 42 itself after the data programming. Accordingly, in such a case as well, the data retention characteristics may decrease.

In other words, in the reference example, it is difficult to suppress the reliability decrease of the nonvolatile semiconductor memory device.

Conversely, in the nonvolatile semiconductor memory device 1 according to the embodiment, at least one of the multiple electrode layers 40 has a wave-like configuration; and the tapered configuration of the memory hole MH is utilized.

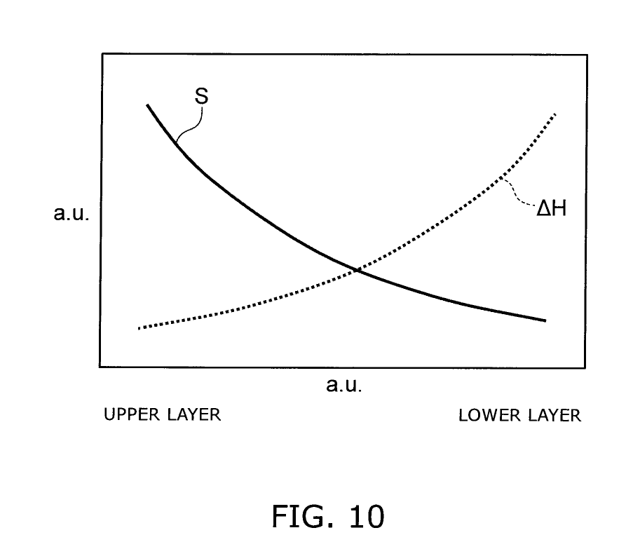

FIG. 10 shows the relationship between the height difference of the electrode layer and the cross-sectional area of the channel body layer for the nonvolatile semiconductor memory device according to the embodiment.

The horizontal axis is an arbitrary value (a.u. (arbitrary units)) of the distance from the upper layer to the lower layer; and the vertical axis shows arbitrary values (a.u.) of the height difference ΔH and a cross-sectional area S.

In the nonvolatile semiconductor memory device 1, at least one of the multiple electrode layers 40 includes the portion H of relatively increasing height from the foundation layer and the portion L of relatively decreasing height from the foundation layer. The height difference ΔH between the portion H of increasing height and the portion L of decreasing height increases toward the foundation layer 10. The channel body layer 20A includes a region where the cross-sectional area S cut perpendicularly to the Z-direction decreases toward the foundation layer 10.

Here, length at most length is defined as maximum length in length of the channel body layer 20A in X direction and Y direction when the channel body layer 20A is cut perpendicularly to the Z-direction. The channel body layer 20A includes a region where the maximum length decreases toward the foundation layer 10.

Thus, in the nonvolatile semiconductor memory device 1, the cross-sectional area S decreases from the upper layer of the stacked body 41 toward the lower layer of the stacked body 41; and the height difference ΔH increases from the upper layer of the stacked body 41 toward the lower layer of the stacked body 41. That is, in the nonvolatile semiconductor memory device 1, the cross-sectional area S decreases as the height difference ΔH increases.

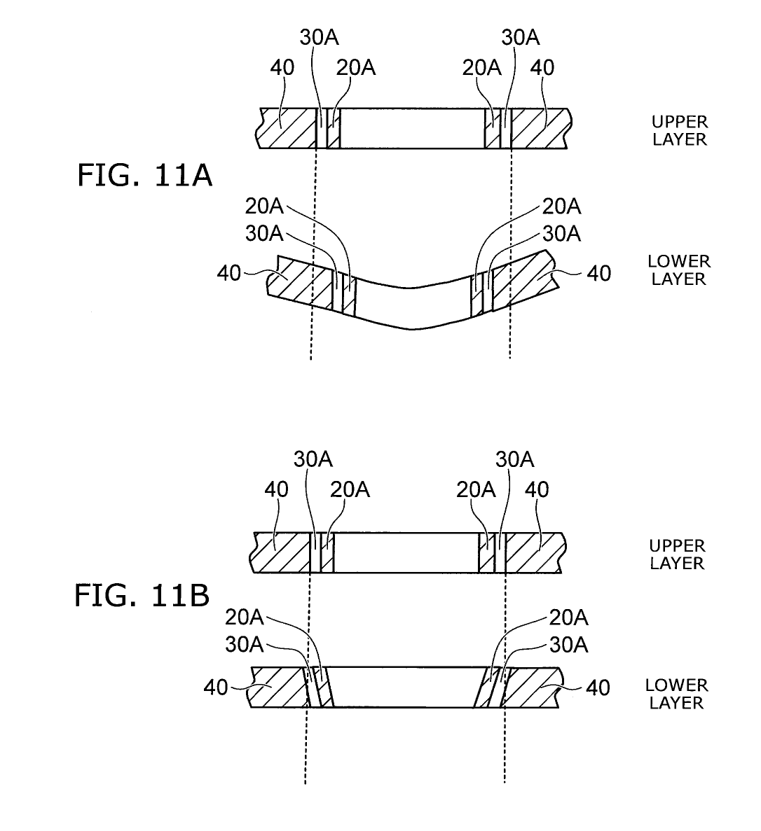

FIG. 11A and FIG. 11B are schematic cross-sectional views showing the electrode layers of the nonvolatile semiconductor memory device according to the embodiment.

Here, the electrode layer 40 at the upper layer of the stacked body 41 and the electrode layer 40 at the lower layer of the stacked body 41 are shown in FIG. 11A and FIG. 11B.

In the nonvolatile semiconductor memory device 1, the cross-sectional area S decreases as the height difference ΔH increases. Accordingly, as shown in FIG. 11A, it may be considered that the curvature of the memory film 30A appears to be greater at the lower layer of the stacked body 41 than at the upper layer of the stacked body 41.

However, an area where the channel body layer 20A is in contact with the memory film 30A increases toward the foundation layer 10. Therefore, an area where the electrode layer 40 is in contact with the memory film 30A increases toward the foundation layer 10. As a result, a potential applied to the memory film 30A by the electrode layer 40 is suppressed toward the foundation layer 10 even granting that the curvature of the memory film 30A is greater at the lower layer of the stacked body 41 than at the upper layer of the stacked body 41. Therefore, the amount of charge that is stored in each of the memory films 30A is, for example, substantially the same.

Furthermore, the situation is different when each of the flexed electrode layers 40 is returned to the flat state. The appearance when each of the flexed electrode layers 40 is returned to the flat state is shown in FIG. 11B. In the nonvolatile semiconductor memory device 1, from the upper layer of the stacked body 41 toward the lower layer of the stacked body 41, the cross-sectional area S decreases but the height difference ΔH increases. Accordingly, when each of the flexed electrode layers 40 is returned to the flat state, the memory hole MH diameter is enlarged; and the curvatures are in balance for the memory films 30A in the stacked body 41. That is, in the nonvolatile semiconductor memory device 1, after the data programming, the amount of charge that is stored in each of the memory films 30A is, for example, substantially the same.

According to the embodiment, it is unnecessary to reduce the film thickness of each of the electrode layers 40. Accordingly, each of the memory films 30A is not easily affected by the electric fields from the electrode layers 40 positioned above and below. Also, each of the memory films 30A is not easily affected by the charge stored in the memory films 30A positioned above and below. Further, the charge is not easily trapped in the insulating layer 42.

Thus, in the nonvolatile semiconductor memory device 1 according to the embodiment, the data retention characteristics improve. That is, a nonvolatile semiconductor memory device having high reliability is realized.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile semiconductor memory device, comprising:
a foundation layer;
a stacked body provided on the foundation layer, the stacked body including a plurality of first electrode layers stacked alternately with a plurality of first insulating layers, at least one of the plurality of first electrode layers including a first portion and a second portion, a first length between the first portion and the foundation layer being longer than a second length between the second portion and the foundation layer, difference between the first length and the second length increasing toward the foundation layer;
a first semiconductor member piercing the second portion in the stacked body, the first semiconductor member extending in a direction of the stacking of the plurality of first electrode layers and the plurality of first insulating layers, the first semiconductor member including a first region where maximum length of the first semiconductor member cut perpendicularly to the direction decreases toward the foundation layer; and
a memory film provided between the first semiconductor member and each of the plurality of first electrode layers.

2. The device according to claim 1, wherein a cross-sectional area of the first semiconductor member in a cut surface cut perpendicularly to the direction decreases as the difference increases.

3. The device according to claim 1, wherein a diameter of the first semiconductor member decreases toward the foundation layer.

4. The device according to claim 1, further comprising a second insulating layer provided between the foundation layer and the first portion of the first electrode layer positioned at the lowermost layer of the plurality of first electrode layers.

5. The device according to claim 4, further comprising a third insulating layer contacting the second insulating layer and extending in the direction in the stacked body,
the third insulating layer contacting the first portion of one of the plurality of first electrode layers.

6. The device according to claim 1, further comprising a second semiconductor member piercing the second portion in the stacked body, the second semiconductor member extending in the direction of the stacking of the plurality of first electrode layers and the plurality of first insulating layers, the second semiconductor member including a second region where maximum length of the first semiconductor member cut perpendicularly to the direction decreases toward the foundation layer.

7. The device according to claim 6, wherein a diameter of the second semiconductor member decreases toward the foundation layer.

8. The device according to claim 6, wherein the first portion is provided between the first semiconductor member and the second semiconductor member.

9. The device according to claim 6, further comprising a second insulating layer provided between the foundation layer and the first portion of the first electrode layer positioned at the lowermost layer of the plurality of first electrode layers,
the second insulating layer being provided between the first semiconductor member and the second semiconductor member.

10. The device according to claim 6, further comprising a third semiconductor member, a lower end of the first semiconductor member being connected to a lower end of the second semiconductor member via the third semiconductor member.

11. The device according to claim 10, further comprising a second electrode between the foundation layer and the stacked body, the third semiconductor member being connected to the second electrode via a fourth insulating layer.

12. The device according to claim 5, further comprising a second semiconductor member piercing the second portion in the stacked body, the second semiconductor member extending in the direction of the stacking of the plurality of first electrode layers and the plurality of first insulating layers, the second semiconductor member including a second region where maximum length of the first semiconductor member cut perpendicularly to the direction decreases toward the foundation layer,
the third insulating layer being provided between the first semiconductor member and the second semiconductor member.

13. The device according to claim 5, wherein one of the plurality of first electrode layers is electrically insulated from another of the plurality of first electrode layers beside the one of the plurality of first electrode layers with the third insulating layer.

14. A method for manufacturing a nonvolatile semiconductor memory device, comprising:
forming a semiconductor layer on a foundation layer;
forming a second insulating layer inside the semiconductor layer;
etching an upper surface of the semiconductor layer until the second insulating layer protrudes from the upper surface of the semiconductor layer;
forming a stacked body on the second insulating layer and on the semiconductor layer, the stacked body including a plurality of electrode layers stacked alternately with a plurality of first insulating layers, at least one of the plurality of electrode layers including a first portion and a second portion, a first length between the first portion and the foundation layer being longer than a second length between the second portion and the foundation layer, difference between the first length and the second length increasing toward the foundation layer;
forming a hole piercing the second portion, the hole piercing the stacked body in a direction of the stacking of the plurality of electrode layers and the plurality of first insulating layers, and the hole including a region where maximum length of the hole cut perpendicularly to the direction decreases toward the foundation layer; and
forming a memory film and a semiconductor member on an inner wall of the hole, the memory film being interposed between the semiconductor member and the inner wall.

15. The method according to claim 14, wherein a bottom of the second insulating layer is positioned under an upper surface of the semiconductor layer after the upper surface of the semiconductor layer is etched.

16. The method according to claim 14, wherein a surface having the upper surface of the semiconductor layer and an upper surface of the second insulating layer is a wavy surface after the upper surface of the semiconductor layer is etched.

17. The method according to claim 14, wherein the first portion of one of the plurality of electrode layers are positioned on the second insulating layer after the forming of the stacked body.

18. The method according to claim 14, further comprising forming a third insulating layer contacting the second insulating layer and extending in the direction in the stacked body after the forming of the stacked body.

19. The method according to claim 14, wherein the maximum length decreases as the difference increases after the making of the hole.

20. The method according to claim 14, wherein the hole inner diameter decreases toward the foundation layer after the making of the hole.
